(19) United States
(12) Patent Application Publication
(10) Pub. No.: US 2025/0337368 A1
(43) Pub. Date: Oct. 30, 2025

(54) LOW DROPOUT REGULATOR WITH ALTERNATIVE LOOP CONTROL

(71) Applicant: Taiwan Semiconductor Manufacturing Company, Ltd., Hsinchu (TW)

(72) Inventor: Che-Min Hung, Zhubei City (TW)

(21) Appl. No.: 18/645,564

(22) Filed: Apr. 25, 2024

(51) Int. Cl. H03F 1/34; G05F 1/565; G05F 1/575; H03F 3/45

(52) U.S. Cl. CPC H03F 1/342; G05F 1/565; G05F 1/575; H03F 3/45475

(57) ABSTRACT

A device including an amplifier having a positive input terminal, a negative input terminal, and an output terminal, the positive input terminal configured to receive a reference voltage source; a select circuit having a first input terminal, a second input terminal, and a select circuit output terminal that is electrically coupled to the negative input terminal; and a loop control circuit having an input electrically coupled to the output terminal of the amplifier, a first control output electrically coupled to the first input terminal, and a second control output electrically coupled to the second input terminal. The select circuit is configured to provide a first signal from the first control output to the negative input terminal in standby mode and a second signal from the second control output to the negative input terminal in nap mode.

### BACKGROUND

Low dropout (LDO) regulators come in many different topologies, including Class A, Class AB, source follower (SF), and other topologies. Typically, except for the Class AB topology, the output voltage of the LDO regulator is regulated in only one direction. As a result, a “kicker” circuit is often used to adjust the output voltage of the LDO regulators that regulate the output voltage in only one direction, such as in Class A and SF topologies. Often, the kicker circuit is controlled by a controller or a detector with a timer. Also, often, activating the kicker circuit results in a longer recovery time for the output voltage of the LDO regulator.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating a device that provides feedback loop control signals to an amplifier to provide a device output voltage Vout in standby mode and in NAP mode, in accordance with some embodiments.

FIG. 2 is a diagram schematically illustrating an LDO regulator device, in accordance with some embodiments.

FIG. 3 is a diagram schematically illustrating simulation waveforms of an LDO regulator with a kicker circuit and an LDO regulator with the dual feedback loop control signals, in accordance with some embodiments.

FIG. 4 is a diagram schematically illustrating a method of operating an LDO regulator device, in accordance with some embodiments.

FIG. 5 is a block diagram schematically illustrating an example of a computer system configured to provide the electronic devices, semiconductor devices, and methods of the current disclosure, in accordance with some embodiments.

FIG. 6 is a block diagram of a semiconductor device manufacturing system and a semiconductor device manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Many systems include a NAP mode (SLEEP mode) for reducing power consumption of the system. Sometimes, in an LDO regulator, a reference voltage VREF is adjusted to a lower voltage level in the NAP mode to reduce current, including output leakage current, and power consumption of the LDO regulator. When entering NAP mode, the reference voltage VREF is adjusted to a lower voltage, such that the output voltage of the LDO regulator is larger than the reference voltage VREF. As a result, an operational amplifier that receives the reference voltage VREF at a positive input terminal of the amplifier and the output voltage of the LDO regulator at a negative input terminal of the amplifier biases off N-channel pass-through transistors of the LDO regulator that have their gates attached to the output of the amplifier and that regulate the output voltage of the LDO regulator. The kicker circuit is activated to discharge the output voltage of the LDO regulator, such that the amplifier re-regulates the output voltage of the LDO regulator to the new target voltage of the lower voltage reference VREF. The kicker circuit is disabled or deactivated after a time T_time that includes the discharge time. Thus, an LDO regulator with the kicker circuit provides an output voltage waveform that includes at least one wait time T_time for completing the discharge phase and recovery of the output voltage.

Disclosed embodiments provide a device that has at least two loop control signals provided to the amplifier of the LDO regulator, such as to the negative input terminal of the amplifier, to control the transient response of the output voltage of the amplifier and the output voltage of the LDO regulator. A first loop control signal is provided to the negative input terminal of the amplifier in standby mode and a second loop control signal is provided to the negative input terminal of the amplifier in NAP mode. The device does not include a kicker circuit, such that the kicker circuit and the discharge phase are eliminated, which reduces the recovery time for regulating the output voltages. The device shortens the recovery time of the output voltage of the LDO regulator, such as when switching the device into NAP mode and switching the device between the NAP mode and the standby mode. Also, the device reduces power consumption in the NAP mode, and power consumption is further reduced since the device does not include the kicker circuit.

Disclosed embodiments further provide a device that includes an amplifier having a positive input terminal, a negative input terminal, and an output terminal. A reference voltage source is electrically coupled to the positive input terminal. A select circuit has a first input terminal, a second input terminal, and a select circuit output terminal that is electrically coupled to the negative input terminal. A loop control circuit has an input electrically coupled to the output terminal of the amplifier. Also, the loop control circuit includes a first control output electrically coupled to the first input terminal of the select circuit and a second control output electrically coupled to the second input terminal of the select circuit. The select circuit is configured to provide a first control signal from the first control output to the negative input terminal in standby mode and a second control signal from the second control output to the negative input terminal in NAP mode. Thus, the device has the first control signal and the second control signal, which are provided to the amplifier of the LDO regulator to control the transient response of the output voltage of the amplifier and the output voltage of the LDO regulator.

In some embodiments, the device includes a device control circuit configured to control the reference voltage source to provide a standby reference voltage in the standby mode and a nap reference voltage in the NAP mode and to control the select circuit to select the first control signal in the standby mode and the second control signal in the NAP mode. In some embodiments, the select circuit is or includes a multiplexer having the first input terminal, the second input terminal, and the select circuit output terminal that is electrically coupled to the negative input terminal of the amplifier.

Advantages of the device include an additional or alternative control loop for eliminating the kicker circuit and the discharge time, speeding up the transient recovery time of the output voltages of the amplifier and the LDO regulator, the device shortens the recovery time from a low voltage level to a high voltage level, the device can be used in conventional LDO regulators, and the device can be used in low power applications that include a NAP mode.

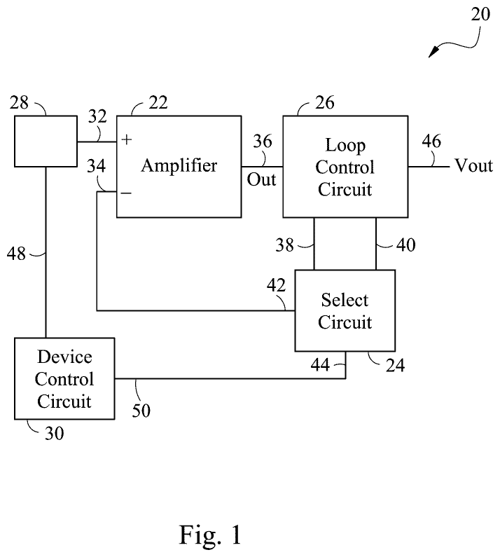

FIG. 1 is a diagram schematically illustrating a device 20 that provides feedback loop control signals to an amplifier 22 to provide a device output voltage Vout in standby mode and in NAP mode, in accordance with some embodiments. The device 20 provides a first feedback loop control signal to the amplifier 22 in standby mode and a second feedback loop control signal to the amplifier 22 in NAP mode. The device 20 includes the amplifier 22, a select circuit 24, a loop control circuit 26, a reference voltage source 28 and, in some embodiments, a device control circuit 30. In some embodiments, the device 20 is a semiconductor device, an integrated circuit device, an electronic device, and/or an LDO regulator device.

The amplifier 22 has a positive input terminal 32, a negative input terminal 34, and an output terminal 36. In some embodiments, the amplifier 22 is an error amplifier. In some embodiments, the amplifier 22 is a differential amplifier. In some embodiments, the device 20 includes a resistor and capacitor (RC) circuit electrically connected to the output terminal 36 of the amplifier 22.

The select circuit 24 has a first input terminal 38, a second input terminal 40, and a select circuit output terminal 42 that is electrically coupled to the negative input terminal 34 of the amplifier 22. Also, the select circuit 24 has a select input terminal 44 that receives a nap input signal for switching between providing a first signal from the first input terminal 38 in standby mode and a second signal from the second input terminal 40 in NAP mode. In some embodiments, the select circuit 24 is a multiplexer.

The loop control circuit 26 has an input electrically coupled to the output terminal 36 of the amplifier 22, a first control output electrically coupled to the first input terminal 38 of the select circuit 24, a second control output electrically coupled to the second input terminal 40 of the select circuit 24, and an output terminal 46. The loop control circuit 26 provides the first feedback loop control signal at the first control output and the second feedback loop control signal at the second control output. The select circuit 24 is configured to provide the first feedback loop control signal from the first control output to the negative input terminal 34 in standby mode and the second feedback loop control signal from the second control output to the negative input terminal 34 in NAP mode.

The reference voltage source 28 is electrically coupled to the positive input terminal 32 of the amplifier 22. The reference voltage source 28 is configured to provide a standby reference voltage to the positive input terminal 32 of the amplifier 22 in the standby mode and a nap reference voltage to the positive input terminal 32 of the amplifier 22 in the NAP mode.

The device control circuit 30 is electrically coupled to the reference voltage source 28 by communications path 48 and to the select input terminal 44 of the select circuit 24 by communications path 50.

In operation the device control circuit 30 controls the reference voltage source 28 to provide the standby reference voltage to the positive input terminal 32 of the amplifier 22 in the standby mode and the nap reference voltage to the positive input terminal 32 of the amplifier 22 in the NAP mode, and to control the select circuit 24 to select the first feedback loop control signal in the standby mode and the second feedback loop control signal in the NAP mode.

Thus, in standby mode, the amplifier 22 receives the standby reference voltage at the positive input terminal 32 and the first feedback loop control signal at the negative input terminal 34. The amplifier 22 provides an output voltage to the loop control circuit 26 that provides the first feedback loop control signal to the select circuit 24 and an output voltage Vout at the output terminal 46.

To enter the NAP mode, the reference voltage received at the positive input terminal 32 is switched to the nap reference voltage, which is a lower voltage than the standby reference voltage, and the select circuit 24 provides the second feedback loop control signal to the negative input terminal 34 of the amplifier 22. Switching to the second feedback loop control signal at the negative input terminal 34 of the amplifier 22, eliminates the discharge phase and transient noise on the output 36 of the amplifier 22. In Nap mode, the output of the amplifier 22 is held relatively constant, which ensures the minimum output voltage Vout at the output terminal 46. In some embodiments, this dual feedback loop control signal approach saves about 1.3 micro-seconds (us) in regulation time.

When leaving the NAP mode and switching to the standby mode, the amplifier 22 receives the standby reference voltage at the positive input terminal 32 and the first feedback loop control signal at the negative input terminal 34. The output of the amplifier 22 is charged to the new target value of the standby reference voltage. In some embodiments, this takes about 0.2 nanoseconds (ns) of recovery time.

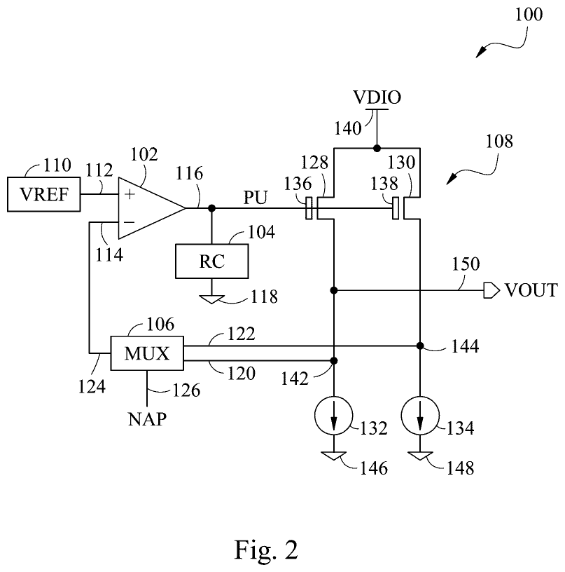

FIG. 2 is a diagram schematically illustrating an LDO regulator device 100, in accordance with some embodiments. The LDO regulator 100 includes an amplifier 102 that receives a standby reference voltage and a first feedback loop control signal in standby mode and a nap reference voltage and a second feedback loop control signal in NAP mode to control the output voltage Vout of the LDO regulator 100.

The LDO regulator 100 includes the amplifier 102, an RC circuit 104, a multiplexer 106, a loop control circuit 108, and a reference voltage source 110. In some embodiments, the LDO regulator 100 is electrically connected to a device control circuit (not shown) that controls operation of the LDO regulator 100. In some embodiments, the device control circuit is like the device control circuit 30 of FIG. 1. In some embodiments, the LDO regulator 100 is a semiconductor device, an integrated circuit device, and/or an electronic device.

The amplifier 102 has a positive input terminal 112, a negative input terminal 114, and an output terminal 116. The amplifier 102 is an error amplifier, also referred to as a differential amplifier. The RC circuit 104 is electrically connected on one side to the output terminal 116 of the amplifier 102 and on another side to a reference 118, such as ground.

The multiplexer 106 has a first input terminal 120, a second input terminal 122, and a multiplexer output terminal 124 that is electrically coupled to the negative input terminal 114 of the amplifier 102. Also, the multiplexer 106 has a select input terminal 126 that receives a nap input signal NAP for switching between the first signal from the first input terminal 120 in standby mode and the second signal from the second input terminal 122 in NAP mode.

The loop control circuit 108 includes a first pass transistor 128, a second pass transistor 130, a first current source 132, and a second current source 134. The first pass transistor 128 has a first gate 136 electrically coupled to the output terminal 116 of the amplifier 102, and the second pass transistor 130 has a second gate 138 electrically coupled to the output terminal 116 of the amplifier 102. The first pass transistor 128 has a first drain/source path that includes a first end electrically coupled to receive an input voltage source VDIO 140 and a second end electrically coupled to a first control output 142. The second pass transistor 130 has a second drain/source path that includes a third end electrically coupled to receive the input voltage source VDIO 140 and a fourth end electrically coupled to the second control output 144. The first drain/source path is electrically connected to the first current source 132 that is electrically connected to a reference 146, such as ground, and the second drain/source path is electrically connected to the second current source 134 that is electrically connected to a reference 148, such as ground. In some embodiments, each of the first pass transistor 128 and the second pass transistor 130 is an N-type metal-oxide semiconductor (NMOS) transistor.

The first control output 142 is electrically coupled to the first input terminal 120 of the multiplexer 106 and the output terminal 150, the second control output 144 is electrically coupled to the second input terminal 122 of the multiplexer 106. The loop control circuit 108 provides the first feedback loop control signal at the first control output 142 and the second feedback loop control signal at the second control output 144. The multiplexer 106 provides the first feedback loop control signal from the first control output 142 to the negative input terminal 114 in standby mode and the second feedback loop control signal from the second control output 144 to the negative input terminal 114 in NAP mode.

The reference voltage source 110 is electrically coupled to the positive input terminal 112 of the amplifier 102. The reference voltage source 110 provides a standby reference voltage to the positive input terminal 112 of the amplifier 102 in the standby mode and a nap reference voltage to the positive input terminal 112 of the amplifier 102 in the NAP mode.

In some embodiments, a device control circuit is electrically coupled to the reference voltage source 110 and to the NAP input terminal 126 of the multiplexer 106. The device control circuit controls the reference voltage source 110 to provide the standby reference voltage to the positive input terminal 112 of the amplifier 102 in the standby mode and the nap reference voltage to the positive input terminal 112 of the amplifier 102 in the NAP mode, and the device control circuit controls the multiplexer 106 to select the first feedback loop control signal in the standby mode and the second feedback loop control signal in the NAP mode.

Thus, in standby mode, the amplifier 102 receives the standby reference voltage at the positive input terminal 112 and the first feedback loop control signal at the negative input terminal 114. The amplifier 102 provides an output voltage to the loop control circuit 108 that provides the first feedback loop control signal to the multiplexer 106 and the output voltage Vout at the output terminal 150.

To enter the NAP mode, the reference voltage received at the positive input terminal 112 is switched to the nap reference voltage, which is a lower voltage than the standby reference voltage, and the multiplexer 106 provides the second feedback loop control signal to the negative input terminal 114 of the amplifier 102. Switching to the second feedback loop control signal at the negative input terminal 114 of the amplifier 102 eliminates the discharge phase and transient noise on the output 116 of the amplifier 102. In Nap mode, the output of the amplifier 102 is held relatively constant, which ensures the minimum output voltage Vout at the output terminal 150. In some embodiments, this dual feedback loop control signal approach saves about 1.3 us in regulation time.

When leaving the NAP mode and switching to the standby mode, the amplifier 102 receives the standby reference voltage at the positive input terminal 112 and the first feedback loop control signal at the negative input terminal 114. The output of the amplifier 102 is charged to the new target value of the standby reference voltage. In some embodiments, this takes about 0.2 ns of recovery time.

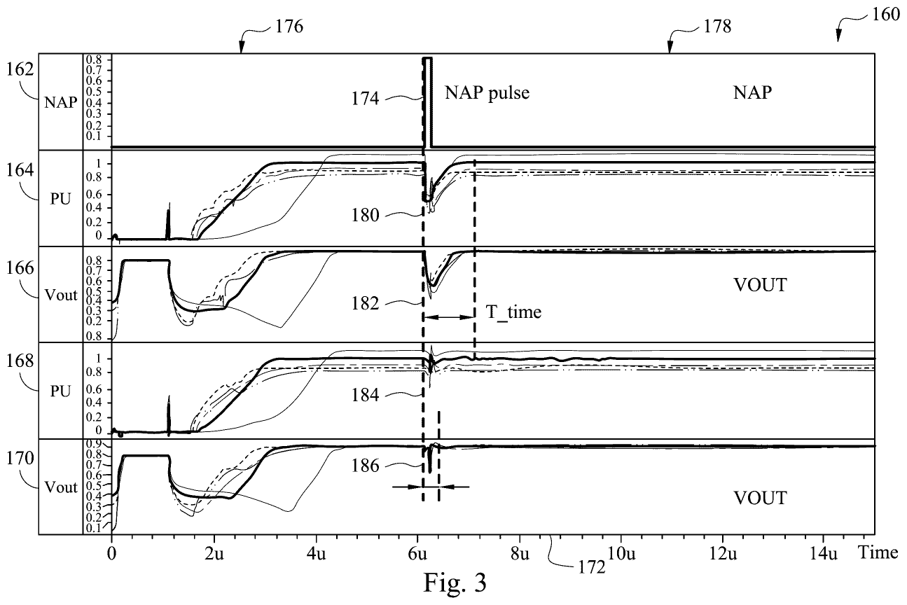

FIG. 3 is a diagram schematically illustrating simulation waveforms 160 of an LDO regulator with a kicker circuit and an LDO regulator with the dual feedback loop control signals, in accordance with some embodiments.

The simulation waveforms 160 include a nap signal waveform 162, amplifier output terminal waveforms 164 for the LDO regulator with the kicker circuit, LDO regulator output terminal waveforms 166 for the LDO regulator with the kicker circuit, amplifier output terminal waveforms 168 for the LDO regulator with the dual feedback loop control signals, and LDO regulator output terminal waveforms 170 for the LDO regulator with the dual feedback loop control signals. Time is graphed along the x-axis 172.

The nap signal waveform 162 includes a nap signal pulse 174 that puts the LDO regulator with the kicker circuit and the LDO regulator with the dual feedback loop control signals into NAP mode. Prior to the nap signal pulse 174, each of the LDO regulator with the kicker circuit and the LDO regulator with the dual feedback loop control signals is in the standby mode 176. After the nap signal pulse 174 switches off, each of the LDO regulator with the kicker circuit and the LDO regulator with the dual feedback loop control signals switch to the standby mode 178.

The amplifier output terminal waveforms 164 for the LDO regulator with the kicker circuit dip to a lower voltage 180 in response to the nap signal pulse 174. The kicker circuit is activated and the amplifier output terminal waveforms 164 recover to the target voltage of the NAP mode and then to the standby mode 178, after a time T_time. Also, the LDO regulator output terminal waveforms 166 for the LDO regulator with the kicker circuit dip to a lower voltage 182 in response to the nap signal pulse 174. The kicker circuit is activated and the LDO regulator output terminal waveforms 166 recover to the target voltage of the NAP mode and then the standby mode 178, after a time T_time. Thus, from switching to the NAP mode in response to the nap signal pulse 174 to recovery of the two output terminal waveforms in standby mode 178 takes the time T_time. In some embodiments, the time T_time is about 630 ns. In some embodiments, the time T_time is about 1.3 us.

The amplifier output terminal waveforms 168 for the LDO regulator with the dual feedback loop control signals dip to a slightly lower voltage 184 for a shorter time in response to the nap signal pulse 174. The second feedback loop control signal is provided to the amplifier 102 and the amplifier output terminal waveforms 168 for the LDO regulator with the dual feedback loop control signals recover to the target voltage of the NAP mode. Then, the first feedback loop control signal is provided to the amplifier 102 and the amplifier output terminal waveforms 168 for the LDO regulator with the dual feedback loop control signals recover to the target voltage of the standby mode 178. In some embodiments, from switching to the NAP mode in response to the nap pulse signal 174 to recovery of the amplifier output terminal waveforms 168 takes about 60 ns, which is much shorter than the T_time of 630 ns or 1.3 us.

The LDO regulator output terminal waveforms 170 for the LDO regulator with the dual feedback loop control signals dip to a slightly lower voltage 186 for a shorter time in response to the nap signal pulse 174. The second feedback loop control signal is provided to the amplifier 102 and the LDO regulator output terminal waveforms 170 for the LDO regulator with the dual feedback loop control signals recover to the target voltage of the NAP mode. Then, the first feedback loop control signal is provided to the amplifier 102 and the LDO regulator output terminal waveforms 170 for the LDO regulator with the dual feedback loop control signals recover to the target voltage of the standby mode 178. In some embodiments, from switching to the NAP mode in response to the nap pulse signal 174 to recovery of the LDO regulator output terminal waveforms 170 takes about 60 ns, which is much shorter than the T_time of 630 ns or 1.3 us.

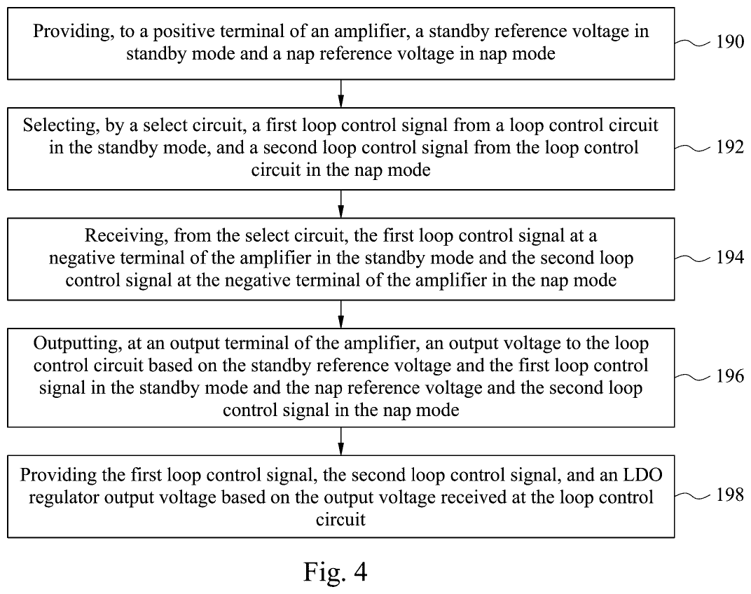

FIG. 4 is a diagram schematically illustrating a method of operating an LDO regulator device, in accordance with some embodiments. In some embodiments, the LDO regulator device is like the device 20 of FIG. 1. In some embodiments, the LDO regulator device is like the LDO regulator device 100 of FIG. 2.

At step 190, the method includes providing, to a positive terminal of an amplifier, a standby reference voltage in standby mode and a nap reference voltage in nap mode. In some embodiments, the amplifier is like the amplifier 22 and the positive terminal is like the positive input terminal 32. In some embodiments, the amplifier is like the amplifier 102 and the positive terminal is like the positive input terminal 112.

At step 192, the method includes selecting, by a select circuit, a first loop control signal from a loop control circuit in the standby mode, and a second loop control signal from the loop control circuit in the nap mode. In some embodiments, the select circuit is like the select circuit 24 and the loop control circuit is like the loop control circuit 26. In some embodiments, the select circuit is like the multiplexer 106 and the loop control circuit is like the loop control circuit 108.

In some embodiments, the selecting, by the select circuit, includes receiving a nap input signal at a select input of the select circuit for switching between the first loop control signal in the standby mode and the second loop control signal in the nap mode.

At step 194, the method includes receiving, from the select circuit, the first loop control signal at a negative terminal of the amplifier in the standby mode and the second loop control signal at the negative terminal of the amplifier in the nap mode. In some embodiments, the amplifier is like the amplifier 22 and the negative terminal is like the negative input terminal 34. In some embodiments, the amplifier is like the amplifier 102 and the negative terminal is like the negative input terminal 114.

At step 196, the method includes outputting, at an output terminal of the amplifier, an output voltage to the loop control circuit based on the standby reference voltage and the first loop control signal in the standby mode and the nap reference voltage and the second loop control signal in the nap mode. In some embodiments, the amplifier is like the amplifier 22 and the output terminal is like the output terminal 36. In some embodiments, the amplifier is like the amplifier 102 and the output terminal is like the output terminal 116.

In some embodiments, the outputting, at an output terminal of the amplifier, the output voltage to the loop control circuit includes receiving the output voltage at a first gate of a first pass transistor that has a first drain/source path that includes a first end electrically coupled to receive an input voltage source and a second end electrically coupled to provide the first loop control signal, and at a second gate of a second pass transistor that has a second drain/source path that includes a third end electrically coupled to receive the input voltage source and a fourth end electrically coupled to provide the second loop control signal.

At step 198, the method includes providing the first loop control signal, the second loop control signal, and an LDO regulator output voltage based on the output voltage received at the loop control circuit. In some embodiments, the method comprises providing, by a device control circuit, first control signals to a reference voltage source to provide the standby reference voltage in the standby mode and the nap reference voltage in the nap mode and second control signals to the select circuit to select the first loop control signal in the standby mode and the second loop control signal in the nap mode. In some embodiments, the device control circuit is like the device control circuit 30.

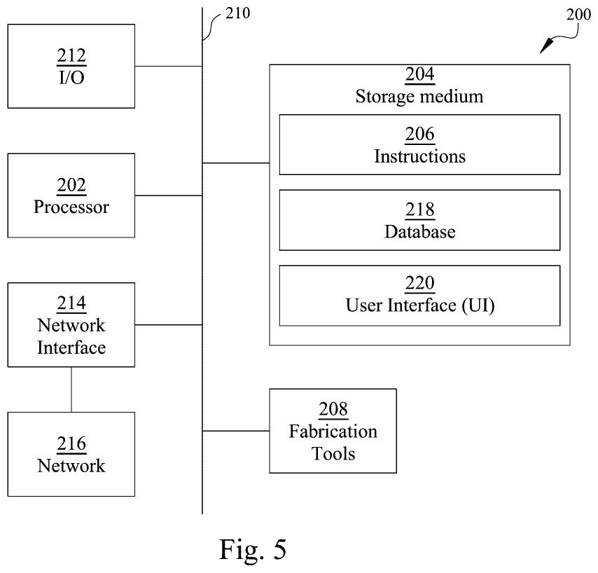

FIG. 5 is a block diagram schematically illustrating an example of a computer system 200 configured to provide the electronic devices, semiconductor devices, and methods of the current disclosure, in accordance with some embodiments. Some or all the design, layout, and manufacture of the semiconductor devices, also referred to as semiconductor circuits, can be performed by or with the aid of the computer system 200. Also, some or all the design, layout, and manufacture of the electronic devices can be performed by or with the aid of the computer system 200. In some embodiments, the computer system 200 includes an electronic design automation (EDA) system. In some embodiments, the semiconductor devices are ICs.

In some embodiments, the system 200 is a general-purpose computing device including a processor 202 and a non-transitory, computer-readable storage medium 204. The computer-readable storage medium 204 may be encoded with, e.g., store, computer program code such as executable instructions 206. Execution of the instructions 206 by the processor 202 provides (at least in part) a design tool that implements a portion or all the functions of the system 200, such as pre-layout simulations, post-layout simulations, routing, rerouting, and final layout for manufacturing. Further, fabrication tools 208 are included to further layout and physically implement the design and manufacture of the semiconductor devices. In some embodiments, execution of the instructions 206 by the processor 202 provides (at least in part) a design tool that implements a portion or all the functions of the system 200. In some embodiments, the system 200 includes a commercial router. In some embodiments, the system 200 includes an automatic place and route (APR) system.

The processor 202 is electrically coupled to the computer-readable storage medium 204 by a bus 210 and to an I/O interface 212 by the bus 210. A network interface 214 is also electrically connected to the processor 202 by the bus 210. The network interface 214 is connected to a network 216, so that the processor 202 and the computer-readable storage medium 204 can connect to external elements using the network 216. The processor 202 is configured to execute the computer program code or instructions 206 encoded in the computer-readable storage medium 204 to cause the system 200 to perform a portion or all the functions of the system 200, such as providing the semiconductor devices and methods of the current disclosure and other functions of the system 200. In some embodiments, the processor 202 is a central processing unit (CPU), a multi-processor, a distributed processing system, an application specific integrated circuit (ASIC), and/or a suitable processing unit.

In some embodiments, the computer-readable storage medium 204 is an electronic, magnetic, optical, electromagnetic, infrared, and/or semiconductor system or apparatus or device. For example, the computer-readable storage medium 204 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 204 can include a compact disk read only memory (CD-ROM), a compact disk read/write memory (CD-R/W), and/or a digital video disc (DVD).

In some embodiments, the computer-readable storage medium 204 stores computer program code or instructions 206 configured to cause the system 200 to perform a portion or all the functions of the system 200. In some embodiments, the computer-readable storage medium 204 also stores information which facilitates performing a portion or all the functions of the system 200. In some embodiments, the computer-readable storage medium 204 stores a database 218 that includes one or more of component libraries, digital circuit cell libraries, and databases.

The system 200 includes the I/O interface 212, which is coupled to external circuitry. In some embodiments, the I/O interface 212 includes a keyboard, keypad, mouse, trackball, trackpad, touchscreen, and/or cursor direction keys for communicating information and commands to the processor 202.

The network interface 214 is coupled to the processor 202 and allows the system 200 to communicate with the network 216, to which one or more other computer systems are connected. The network interface 214 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 200 can be performed in two or more systems that are like system 200.

The system 200 is configured to receive information through the I/O interface 212. The information received through the I/O interface 212 includes one or more of instructions, data, design rules, libraries of components and cells, and/or other parameters for processing by the processor 202. The information is transferred to the processor 202 by the bus 210. Also, the system 200 is configured to receive information related to a user interface (UI) through the I/O interface 212. This UI information can be stored in the computer-readable storage medium 204 as a UI 220.

In some embodiments, a portion or all the functions of the system 200 are implemented via a standalone software application for execution by a processor. In some embodiments, a portion or all the functions of the system 200 are implemented in a software application that is a part of an additional software application. In some embodiments, a portion or all the functions of the system 200 are implemented as a plug-in to a software application. In some embodiments, at least one of the functions of the system 200 is implemented as a software application that is a portion of an EDA tool. In some embodiments, a portion or all the functions of the system 200 are implemented as a software application that is used by the system 200. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 200 include fabrication tools 208 for implementing the manufacturing processes of the system 200. For example, based on the final layout, photolithographic masks may be generated, which are used to fabricate the semiconductor device by the fabrication tools 208.

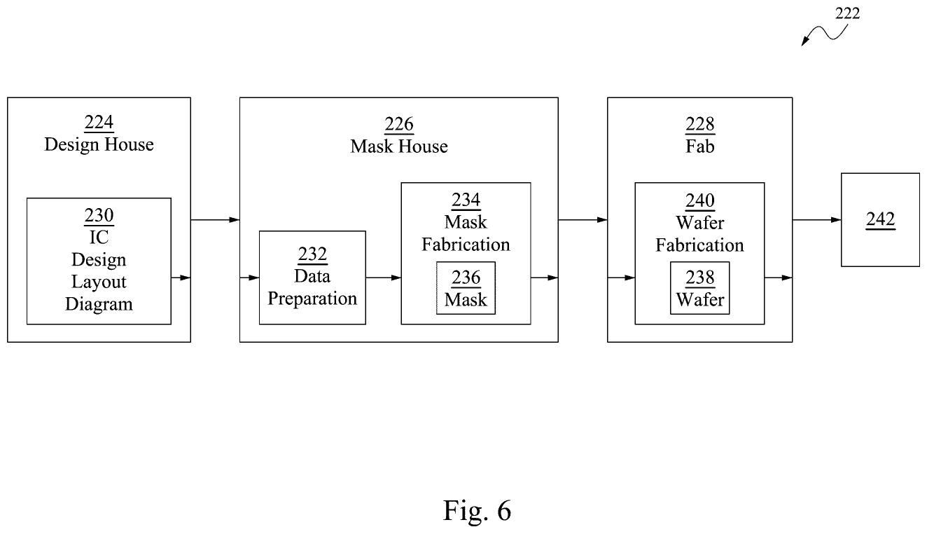

Further aspects of device fabrication are disclosed in conjunction with FIG. 6, which is a block diagram of a semiconductor device manufacturing system 222 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 222.

In FIG. 6, the semiconductor device manufacturing system 222 includes entities, such as a design house 224, a mask house 226, and a semiconductor device manufacturer/fabricator (“Fab”) 228, that interact with one another in the design, development, and manufacturing cycles and/or services related to manufacturing a semiconductor device, such as the semiconductor devices described herein. The entities in the system 222 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 224, the mask house 226, and the semiconductor device fab 228 are owned by a single larger company. In some embodiments, two or more of the design house 224, the mask house 226, and the semiconductor device fab 228 coexist in a common facility and use common resources.

The design house (or design team) 224 generates a semiconductor device design layout diagram 230. The semiconductor device design layout diagram 230 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 230 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 224 implements a design procedure to form a semiconductor device design layout diagram 230. The semiconductor device design layout diagram 230 is presented in one or more data files having information of the geometrical patterns. For example, semiconductor device design layout diagram 230 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 226 includes data preparation 232 and mask fabrication 234. The mask house 226 uses the semiconductor device design layout diagram 230 to manufacture one or more masks 236 to be used for fabricating the various layers of the semiconductor device or semiconductor structure. The mask house 226 performs mask data preparation 232, where the semiconductor device design layout diagram 230 is translated into a representative data file (RDF). The mask data preparation 232 provides the RDF to the mask fabrication 234. The mask fabrication 234 includes a mask writer that converts the RDF to an image on a substrate, such as a mask (reticle) 236 or a semiconductor wafer 238. The design layout diagram 230 is manipulated by the mask data preparation 232 to comply with characteristics of the mask writer and/or criteria of the semiconductor device fab 228. In FIG. 6, the mask data preparation 232 and the mask fabrication 234 are illustrated as separate elements. In some embodiments, the mask data preparation 232 and the mask fabrication 234 can be collectively referred to as mask data preparation.

In some embodiments, the mask data preparation 232 includes an optical proximity correction (OPC) which uses lithography enhancement techniques to compensate for image errors, such as those that can arise from diffraction, interference, other process effects and the like. The OPC adjusts the semiconductor device design layout diagram 230. In some embodiments, the mask data preparation 232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 232 includes a mask rule checker (MRC) that checks the semiconductor device design layout diagram 230 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 230 to compensate for limitations during the mask fabrication 234, which may undo part of the modifications performed by OPC to meet mask creation rules.

In some embodiments, the mask data preparation 232 includes lithography process checking (LPC) that simulates processing that will be implemented by the semiconductor device fab 228. LPC simulates this processing based on the semiconductor device design layout diagram 230 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are to be repeated to further refine the semiconductor device design layout diagram 230.

The above description of mask data preparation 232 has been simplified for the purposes of clarity. In some embodiments, data preparation 232 includes additional features such as a logic operation (LOP) to modify the semiconductor device design layout diagram 230 according to manufacturing rules. Additionally, the processes applied to the semiconductor device design layout diagram 230 during data preparation 232 may be executed in a variety of different orders.

After the mask data preparation 232 and during the mask fabrication 234, a mask 236 or a group of masks 236 are fabricated based on the modified semiconductor device design layout diagram 230. In some embodiments, the mask fabrication 234 includes performing one or more lithographic exposures based on the semiconductor device design layout diagram 230. In some embodiments, an electron-beam (e-beam) or a mechanism of multiple e-beams is used to form a pattern on a mask (photomask or reticle) 236 based on the modified semiconductor device design layout diagram 230. The mask 236 can be formed in various technologies. In some embodiments, the mask 236 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 236 includes a transparent substrate (e.g., fused quartz) and an opaque material (e.g., chromium) coated in the opaque regions of the binary mask. In another example, the mask 236 is formed using a phase shift technology. In a phase shift mask (PSM) version of the mask 236, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 234 is used in a variety of processes. For example, such a mask(s) is used in an ion implantation process to form various doped regions in the semiconductor wafer 238, in an etching process to form various etching regions in the semiconductor wafer 238, and/or in other suitable processes.

The semiconductor device fab 228 includes wafer fabrication 240. The semiconductor device fab 228 is a semiconductor device fabrication business that includes one or more manufacturing facilities for the fabrication of a variety of different semiconductor device products. In some embodiments, the semiconductor device fab 228 is a semiconductor foundry. For example, there may be a manufacturing facility for the front end of line (FEOL) fabrication of a plurality of semiconductor device products, while a second manufacturing facility may provide the BEOL fabrication for the interconnection and packaging of the semiconductor device products, and a third manufacturing facility may provide other services for the foundry business.

The semiconductor device fab 228 uses the mask(s) 236 fabricated by the mask house 226 to fabricate the semiconductor structures or semiconductor devices 242 of the current disclosure. Thus, the semiconductor device fab 228 at least indirectly uses the semiconductor device design layout diagram 230 to fabricate the semiconductor structures or semiconductor devices 242 of the current disclosure. Also, the semiconductor wafer 238 includes a silicon substrate or other proper substrate having material layers formed thereon, and the semiconductor wafer 238 further includes one or more of various doped regions, dielectric features, multilevel interconnects, and the like (formed at subsequent manufacturing steps). In some embodiments, the semiconductor wafer 238 is fabricated by the semiconductor device fab 228 using the mask(s) 236 to form the semiconductor structures or semiconductor devices 242 of the current disclosure. In some embodiments, the semiconductor device fabrication includes performing one or more lithographic exposures based at least indirectly on the semiconductor device design layout diagram 230.

Disclosed embodiments thus include a device that has at least two loop control signals provided to the amplifier of the LDO regulator, such as to the negative input terminal of the amplifier, to control the transient response of the output voltage of the amplifier and the output voltage of the LDO regulator. A first loop control signal is provided to the negative input terminal of the amplifier in standby mode and a second loop control signal is provided to the negative input terminal of the amplifier in NAP mode. The device does not include a kicker circuit, such that the kicker circuit and the discharge phase are eliminated, which reduces the recovery time for regulating the output voltages. The device shortens the recovery time of the output voltage of the LDO regulator, such as when switching the device into NAP mode and switching the device between the NAP mode and the standby mode. Also, the device reduces power consumption in the NAP mode, and the device reduces power consumption further since the device does not include the kicker circuit.

Disclosed embodiments further provide a device that includes an amplifier and a reference voltage source electrically coupled to a positive input terminal of the amplifier. A select circuit has a select circuit output terminal that is electrically coupled to a negative input terminal of the amplifier. A loop control circuit has an input electrically coupled to an output terminal of the amplifier. Also, the loop control circuit includes a first control output electrically coupled to a first input terminal of the select circuit and a second control output electrically coupled to a second input terminal of the select circuit. The select circuit is configured to provide a first control signal from the first control output to the negative input terminal in standby mode and a second control signal from the second control output to the negative input terminal in NAP mode.

In some embodiments, the device includes a device control circuit configured to control the reference voltage source to provide a standby reference voltage in the standby mode and a nap reference voltage in the NAP mode and to control the select circuit to select the first control signal in the standby mode and the second control signal in the NAP mode.

In accordance with some embodiments, a device including an amplifier having a positive input terminal, a negative input terminal, and an output terminal, the positive input terminal configured to receive a reference voltage source; a select circuit having a first input terminal, a second input terminal, and a select circuit output terminal that is electrically coupled to the negative input terminal; and a loop control circuit having an input electrically coupled to the output terminal of the amplifier, a first control output electrically coupled to the first input terminal, and a second control output electrically coupled to the second input terminal. The select circuit is configured to provide a first signal from the first control output to the negative input terminal in standby mode and a second signal from the second control output to the negative input terminal in nap mode.

In accordance with further embodiments, a low dropout regulator device includes an amplifier, a multiplexer, and a loop control circuit. The amplifier having a positive input terminal, a negative input terminal, and an output terminal, the positive input terminal configured to receive a reference voltage source. The multiplexer having a first input terminal, a second input terminal, and a multiplexer output terminal that is electrically coupled to the negative input terminal of the amplifier. The loop control circuit includes a first pass transistor and a second pass transistor. The first pass transistor having a first gate electrically coupled to the output terminal of the amplifier and a first drain/source path that includes a first end configured to receive an input voltage source and a second end electrically coupled to the first control output that is electrically coupled to the first input terminal. The second pass transistor having a second gate electrically coupled to the output terminal of the amplifier and a second drain/source path that includes a third end configured to receive the input voltage source and a fourth end electrically coupled to the second control output that is electrically coupled to the second input terminal. Where the multiplexer is configured to provide a first signal from the first control output to the negative input terminal in standby mode and a second signal from the second control output to the negative input terminal in NAP mode.

In accordance with still further disclosed aspects, a method of operating a low dropout (LDO) regulator device. The method includes providing, to a positive terminal of an amplifier, a standby reference voltage in standby mode and a nap reference voltage in NAP mode; selecting, by a select circuit, a first loop control signal from a loop control circuit in the standby mode, and a second loop control signal from the loop control circuit in the NAP mode; receiving, from the select circuit, the first loop control signal at a negative terminal of the amplifier in the standby mode and the second loop control signal at the negative terminal of the amplifier in the NAP mode; outputting, at an output terminal of the amplifier, an output voltage to the loop control circuit based on the standby reference voltage and the first loop control signal in the standby mode and the nap reference voltage and the second loop control signal in the NAP mode; and providing the first loop control signal, the second loop control signal, and an LDO regulator output voltage based on the output voltage received at the loop control circuit.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
an amplifier having a positive input terminal, a negative input terminal, and an output terminal, the positive input terminal configured to receive a reference voltage source;
a select circuit having a first input terminal, a second input terminal, and a select circuit output terminal that is electrically coupled to the negative input terminal of the amplifier; and
a loop control circuit having an input electrically coupled to the output terminal of the amplifier, a first control output electrically coupled to the first input terminal, and a second control output electrically coupled to the second input terminal,
wherein the select circuit is configured to provide a first signal from the first control output to the negative input terminal in standby mode and a second signal from the second control output to the negative input terminal in nap mode.

2. The device of claim 1, wherein the positive input terminal is configured to receive a standby reference voltage in the standby mode and a nap reference voltage in the nap mode.

3. The device of claim 1, wherein the select circuit has a select input that receives a nap input signal for switching between providing the first signal in the standby mode and the second signal in the nap mode.

4. The device of claim 1, comprising a device control circuit configured to control the reference voltage source to provide a standby reference voltage in the standby mode and a nap reference voltage in the nap mode and to control the select circuit to select the first signal in the standby mode and the second signal in the nap mode.

5. The device of claim 1, wherein the select circuit includes a multiplexer having the first input terminal, the second input terminal, and the select circuit output terminal that is electrically coupled to the negative input terminal of the amplifier.

6. The device of claim 1, comprising a resistor and capacitor circuit electrically connected to the output terminal of the amplifier.

7. The device of claim 1, wherein the loop control circuit includes a first pass transistor having a first gate electrically coupled to the output terminal of the amplifier, and a second pass transistor having a second gate electrically coupled to the output terminal of the amplifier.

8. The device of claim 7, wherein the first pass transistor has a first drain/source path that includes a first end configured to receive an input voltage source and a second end electrically coupled to the first control output.

9. The device of claim 8, wherein the second pass transistor has a second drain/source path that includes a third end configured to receive the input voltage source and a fourth end electrically coupled to the second control output.

10. The device of claim 9, wherein the first drain/source path is electrically connected to a first current source and the second drain/source path is electrically connected to a second current source.

11. The device of claim 7, wherein each of the first pass transistor and the second pass transistor is an N-type metal-oxide semiconductor (NMOS) transistor.

12. A low dropout regulator device comprising:
an amplifier having a positive input terminal, a negative input terminal, and an output terminal, the positive input terminal configured to receive a reference voltage source;
a multiplexer having a first input terminal, a second input terminal, and a multiplexer output terminal that is electrically coupled to the negative input terminal of the amplifier; and
a loop control circuit including:
a first pass transistor having a first gate electrically coupled to the output terminal of the amplifier and a first drain/source path that includes a first end configured to receive an input voltage source and a second end electrically coupled to the first control output that is electrically coupled to the first input terminal; and
a second pass transistor having a second gate electrically coupled to the output terminal of the amplifier and a second drain/source path that includes a third end configured to receive the input voltage source and a fourth end electrically coupled to the second control output that is electrically coupled to the second input terminal,
wherein the multiplexer is configured to provide a first signal from the first control output to the negative input terminal in standby mode and a second signal from the second control output to the negative input terminal in nap mode.

13. The device of claim 12, wherein the first drain/source path is electrically connected to a first current source and the second drain/source path is electrically connected to a second current source.

14. The device of claim 12, wherein the positive input terminal is configured to receive from the reference voltage source a standby reference voltage in the standby mode and a nap reference voltage in the nap mode.

15. The device of claim 12, wherein the multiplexer has a select input that receives a nap input signal for switching between providing the first signal in the standby mode and the second signal in the nap mode.

16. The device of claim 12, comprising a device control circuit configured to control the reference voltage source to provide a standby reference voltage in the standby mode and a nap reference voltage in the nap mode and to select the first signal in the standby mode and the second signal in the nap mode.

17. A method of operating a low dropout (LDO) regulator device, the method including:
providing, to a positive terminal of an amplifier, a standby reference voltage in standby mode and a nap reference voltage in nap mode;
selecting, by a select circuit, a first loop control signal from a loop control circuit in the standby mode, and a second loop control signal from the loop control circuit in the nap mode;
receiving, from the select circuit, the first loop control signal at a negative terminal of the amplifier in the standby mode and the second loop control signal at the negative terminal of the amplifier in the nap mode;
outputting, at an output terminal of the amplifier, an output voltage to the loop control circuit based on the standby reference voltage and the first loop control signal in the standby mode and the nap reference voltage and the second loop control signal in the nap mode; and
providing the first loop control signal, the second loop control signal, and an LDO regulator output voltage based on the output voltage received at the loop control circuit.

18. The method of claim 17, wherein selecting, by the select circuit, includes receiving a nap input signal at a select input of the select circuit for switching between the first loop control signal in the standby mode and the second loop control signal in the nap mode.

19. The method of claim 17, comprising:
providing, by a device control circuit, first control signals to a reference voltage source to provide the standby reference voltage in the standby mode and the nap reference voltage in the nap mode and second control signals to the select circuit to select the first loop control signal in the standby mode and the second loop control signal in the nap mode.

20. The method of claim 17, wherein outputting, at an output terminal of the amplifier, the output voltage to the loop control circuit includes receiving the output voltage at a first gate of a first pass transistor that has a first drain/source path that includes a first end configured to receive an input voltage source and a second end electrically coupled to provide the first loop control signal, and at a second gate of a second pass transistor that has a second drain/source path that includes a third end configured to receive the input voltage source and a fourth end electrically coupled to provide the second loop control signal.
